(19) United States
(12) Patent Application Publication
(10) Pub. No.: US 2003/0234659 A1
(43) Pub. Date: Dec. 25, 2003

(54) Electrical isolation between pins sharing the same tester channel

(75) Inventor: Jan Zieleman, Hsin-Chu (TW)

Correspondence Address: GEORGE O. SAILE & ASSOCIATES, 28 DAVIS AVENUE, POUGHKEEPSIE, NY, 12603, US

(73) Assignee: Promos Technologies

(21) Appl. No.: 10/177,913

(22) Filed: Jun. 20, 2002

(51) Int. Cl. G01R 31/26

(52) U.S. Cl. 324/765

(57) ABSTRACT

A new apparatus and method for simultaneously testing a plurality of circuit devices are achieved. The apparatus comprises, first, a tester having at least one output signal. A plurality of circuit devices is used. Each circuit device has at least one input signal. Finally, a plurality of auto-reset fuses is used. Each auto-reset fuse is coupled between the tester output signal and one of the input signals of the plurality of circuit devices. The auto-reset fuses automatically switch from low impedance during low current to high impedance during high current. The auto-reset fuses automatically switch from high impedance to low impedance after a waiting time.

### BACKGROUND OF THE INVENTION

(1) Field of the Invention

The invention relates to a method to test multiple circuit devices simultaneously, and, more particularly, to an apparatus and a method to electrically isolate multiple devices using auto-reset fuses.

(2) Description of the Prior Art

Functional circuit testing is a very important process in the art of integrated circuit manufacturing. Testing is performed using very sophisticated, automated testers. These testers are very expensive. Typically, the integrated circuit devices are tested at least two times: at the end of wafer processing and after packaging. The cost of testing circuits is an important part of the overall cost of manufacture.

One method that is used to reduce manufacturing test costs is simultaneous testing. In a simultaneous testing scheme, multiple circuits are tested, in parallel, by the automated tester. Referring now to FIG. 1, a multiple circuit test scheme is shown in simplified, schematic form. A plurality of device under test (DUT) devices DUT1 18 through DUTn 26 are shown. This group of DUT 18, 22, and 26, may comprise, for example, a group of die on a semiconductor wafer or a group of packaged parts inserted into a socket board.

The automated tester 10 comprises a sophisticated set of circuits that is capable of executing a testing program stored in the tester memory. The tester 10 comprises driver circuits 14 that can force voltages or currents onto output channels 30. The tester 10 may be able to drive fixed waveforms or complex digital patterns onto the output channels 30. The tester 10 output channels 30 are inputs to the DUT devices 18, 22, and 26. These inputs are used to exercise each DUT circuit. The outputs pins of the DUT parts 18, 22, and 26, may then be captured by a data acquisition unit of the tester 10. The output data of the DUT parts is then compared to expected output patterns or values stored in the tester 10 memory. If a DUT output response matches the expected response, then the device passes the test. If a DUT output response does not match the expected results, then the DUT fails the test.

In the example schematic, the automated tester 10 drives a single output channel 30 using a drive buffer 14. This channel 30, in turn, is coupled to a signal input pin on each of the DUT1 18 through DUTn 26 in the test group. Therefore, an input pin on each DUT 18, 22, and 26, and the tester output channel 30 are shorted together to form a common node. By sharing the tester output channels between the DUT group members in this way, the scheme minimizes the I/O requirements for the tester. This approach allows the automated tester to test a large number of devices simultaneously.

However, sharing the driver channel 30 between a plurality of DUT 18, 22, and 26, creates a problem if a DUT input pin is shorted. For example, the DUT2 device might exhibit a short circuit between the input pin coupled to the channel 30 and the DUT ground reference due to some manufacturing defect. In this case, the entire common node of the channel 30 and the inputs of the entire DUT group would also be shorted to the ground reference. The entire DUT group would appear to the tester 10 as defective devices and would be labeled as failures or scrapped.

Several prior art inventions relate to methods and circuits for testing multiple circuit devices. U.S. Pat. No. 6,313,658 to Farnworth et al discloses a device and a method for isolating a short-circuited IC die from other IC die on a semiconductor wafer. A short circuit controller is located on each die. The short circuit controller senses a shorting condition and the controls switches in the circuit die that isolated the shorted die. U.S. Pat. No. 6,275,058 to Lunde et al describes a method and an apparatus for disabling high current parts in a parallel test environment. An ASIC device is built into each test socket. A fuse between the tester and the test socket on the VCC line. If the fuse is blown, then the ASIC detects the condition and disables the remaining DUT I/O pins to thereby remove the shorted part from the test. U.S. Pat. No. 5,483,155 to Kannegundla et al teaches a test system and a method for dynamic testing of a plurality of packaged CCD sensors. Isolation networks are placed between the test system and multiple DUT. U.S. Pat. No. 5,953,221 to Kuhn et al discloses a multiple range, power supply unit having automatic switching. A PTC thermistor is used in the current divider circuit.

### SUMMARY OF THE INVENTION

A principal object of the present invention is to provide an effective apparatus for simultaneously testing a plurality of circuit devices.

A further object of the present invention is to provide an apparatus for simultaneously testing devices where a short on any of the multiple devices under test does not interfere with testing of the other devices.

A yet further object of the present invention is to provide shorting isolation using an auto-reset fuse between the shared, tester output channel and the multiple device inputs.

Another yet further object of the present invention is to provide an auto-reset fuse that does not require a control signal.

Another yet further object of the present invention is to provide an auto-reset fuse that is tripped under high current and that is reset to the non-tripped state by a short wait time.

Another principle object of the present invention is to provide a method of simultaneous testing a plurality of circuit devices where shorted devices are automatically isolated from other devices without reducing device yield.

In accordance with the objects of this invention, an apparatus for simultaneously testing a plurality of circuit devices is achieved. The apparatus comprises, first, a tester having at least one output signal. A plurality of circuit devices is used. Each circuit device has at least one input signal. Finally, a plurality of auto-reset fuses is used. Each auto-reset fuse is coupled between the tester output signal and one of the input signals of the plurality of circuit devices. The auto-reset fuses automatically switch from low impedance during low current to high impedance during high current. The auto-reset fuses automatically switch from high impedance to low impedance after a waiting time.

Also in accordance with the objects of the present invention, a method for simultaneously testing a plurality of circuit devices is achieved. A plurality of circuit devices is provided. Each device has at least one input signal. A tester output signal is coupled to the input signals of the plurality of circuit devices through a plurality of auto-reset fuses. The auto-reset fuses automatically switch from low impedance during low current to high impedance during high current. The auto-reset fuses automatically switch from high impedance to low impedance after a waiting time. The plurality of circuit devices is tested by forcing a voltage on the tester output. Any shorted input signals will be isolated by the auto-reset fuses.

### BRIEF DESCRIPTION OF THE DRAWINGS

In the accompanying drawings forming a material part of this description, there is shown:

FIG. 1 illustrates a prior art, multiple device test schematic.

FIG. 2 illustrates the preferred embodiment, tester apparatus of the present invention.

FIG. 3 illustrates the preferred embodiment, tester apparatus applied to testing multiple die on a semiconductor wafer.

FIG. 4 illustrates the preferred embodiment, tester apparatus applied to testing multiple, packaged integrated circuit devices.

FIG. 5 illustrates the preferred embodiment, test method of the present invention.

FIG. 6 illustrates the performance of a positive temperature coefficient (PTC) thermistor.

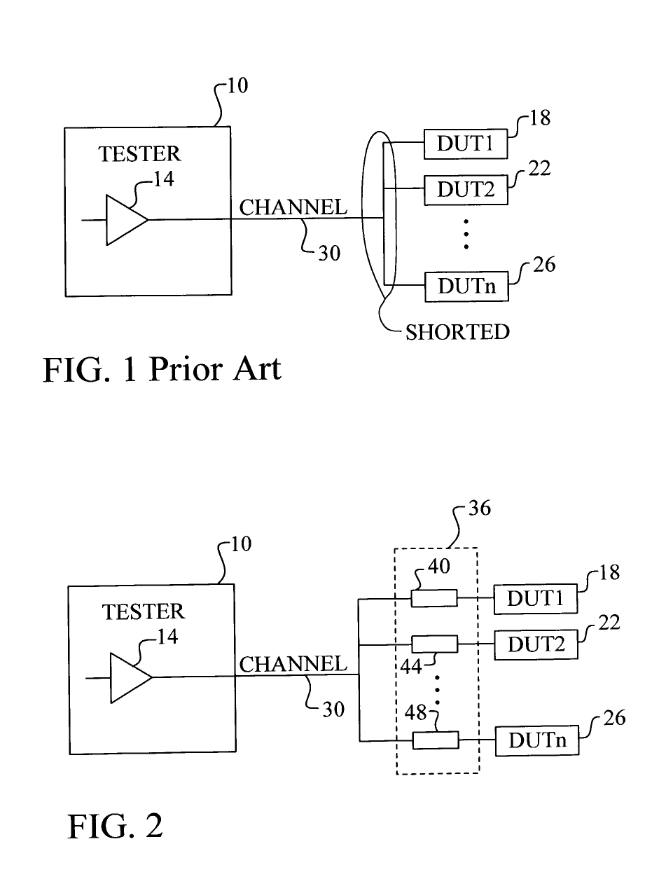

### DESCRIPTION OF THE PREFERRED EMBODIMENTS

The preferred embodiments of the present invention disclose an apparatus and a method for simultaneously testing a plurality of circuit devices. The present invention uses auto-reset fuses between a shared, tester output channel and common, device input pins. The auto-reset fuse prevents shorted, individual devices from interfering with the simultaneous testing of other devices. The auto-reset fuse preferably comprises a positive temperature coefficient (PTC) thermistor that does not require a control signal and that automatically returns to the not-tripped state after a wait time. It should be clear to those experienced in the art that the present invention can be applied and extended without deviating from the scope of the present invention.

Referring now to FIG. 2, the preferred embodiment, tester apparatus of the present invention of the present invention is shown. Several important features of the present invention are shown in the illustration and are further described below. The apparatus comprises, first, a tester 10 having at least one output signal 30. A plurality of circuit devices DUT1 through DUTn 18, 22, and 26, is present for testing. Each circuit device has at least one input signal. Finally, as an important feature, a plurality of auto-reset fuses 40, 44, and 48, is used. Each auto-reset fuse is coupled between the tester output signal CHANNEL 30 and one of the input signals of the plurality of circuit devices 18, 22, and 26. The auto-reset fuses 40, 44, and 48, automatically switch from low impedance during low current to high impedance during high current. The auto-reset fuses 40, 44, and 48, automatically switch from high impedance to low impedance after a waiting time.

As in the prior art example, the tester 10 comprises a driver circuit 14 to drive the current or voltage on the CHANNEL 30. Once again, the single CHANNEL 30 is shared between the common input pins of the plurality of devices under test DUT-DUTn. For example, for identical DUT devices DUT1-DUTn, each device may have an input signal called IN1. Each IN1 pin can be driven using a single tester 10 output buffer 14 where the functional test pattern is held in the tester 10 memory. By sharing the tester output channels between common input pins of the group of DUT devices, a large number of devices can be tested simultaneously.

The most important feature of the present invention is the presence of the auto-reset fuse block 36 comprising a plurality of auto-reset fuses 40, 44, and 48. Each of the auto-reset fuses shares one terminal coupled to the tester output channel CHANNEL 30. The second terminal of each auto-reset fuse is then coupled to the input pin of an individual DUT 18, 22, and 26, of the group of DUT. The auto-reset fuses 40, 44, and 48, share common, operating characteristics. First, the auto-reset fuses must be tripped and reset based only on the current or voltage conditions. No external control signal is required. Second, the auto-reset fuses must be of relatively low impedance (resistance) under normal operating voltage or current conditions. That is, if none of the DUT1-DUTn circuits exhibits a high current draw, then the current flow through each of the auto-reset fuses 40, 44, and 48, should be within a normal operating range. In this case, the auto-reset fuses should all be in the low-impedance mode. In this low-impedance mode, each fuse should appear to the tester 10 as a low value resistor and have little effect upon the circuit operation.

Third, the auto-reset fuses 40, 44, and 48, must automatically change to a high impedance value during an abnormal, high current condition. That is, if any of the DUT exhibits a current draw of much larger than the normal limits, then the auto-reset fuse must respond to this short-circuit current by becoming high impedance. In other words, the resistance of the auto-reset fuse element must become much larger. The auto-reset fuse is said to have tripped due to excessive current. In the high impedance state, the auto-reset fuse limits further current flow into the defective DUT. The other DUT in the group can still be simultaneously and successfully tested.

Fourth, the auto-reset fuses 40, 44, and 48, must automatically reset to the non-tripped, or low impedance, state without an external control signal. In practice, the auto-reset fuses should be able to recover from a tripped condition and return to the non-tripped condition during the time required to index the tester to the next group of wafer die or to load the next group of packaged parts in to the test board.

Preferably, the auto-reset fuses 40, 44, and 48, comprise positive temperature coefficient (PTC) thermistors. Thermistors are electrical devices having a variable resistance value. More particularly, the resistance value of a thermistor will vary due to the temperature of the thermistor. In practice, most resistors have some temperature coefficient effect. This temperature coefficient is particularly large for the thermistor device. Thermistors are often used for indirect measurement of ambient or surface temperature in an electronic system.

Thermistors can have either negative or positive temperature coefficients. In a negative TC thermistor, the resistance value decreases with increasing temperature. In a positive TC thermistor, the resistance value increases with increasing temperature. Referring now to FIG. 6, a PTC thermistor operating curve is shown. In the temperature response curve 180 shown, the thermistor resistance is shown on a logarithmic scale. The typical PTC thermistor operates in two regions 197 and 198. In REGION 1 197, the base resistance of the thermistor has a relatively low temperature coefficient. The thermistor may be designed, for example, to operate in low TC region around 25 degrees C. 190.

At higher operating temperatures, the thermistor transitions to a second operating region 198. In REGION 2 198, the positive TC effect is seen. Small increases in the operating temperature result in large increases in the thermistor resistance value. The switching temperature T_{SW} 195 of the thermistor can be controlled by varying thermistor design parameters.

In the present invention, the auto-reset fuses preferably comprise PTC thermistors. Under low current conditions, as when none of the DUT group has a short circuit, each PTC thermistor operates in REGION 1 and exhibits a low resistance. However, if a DUT has a short, and if this short causes a large current flow, then the PTC thermistor will increase in temperature due to IR heating. When the thermistor passes the switching temperature, T_{SW} 195, it will enter REGION 2 and quickly change to high impedance. This high impedance will eliminate further high current through the shorted DUT pin.

Note that the PTC thermistor will return to the REGION 1 state of operation once the thermistor temperature falls below the switching temperature T_{SW} 195. Therefore, the auto-reset fuse will automatically reset to the low impedance state after a sufficient cooling time. In practice, it is found that the time required for indexing to a new group of wafer die or for loading a new group of packaged parts is sufficient to allow a tripped PTC thermistor to return to REGION 1 197.

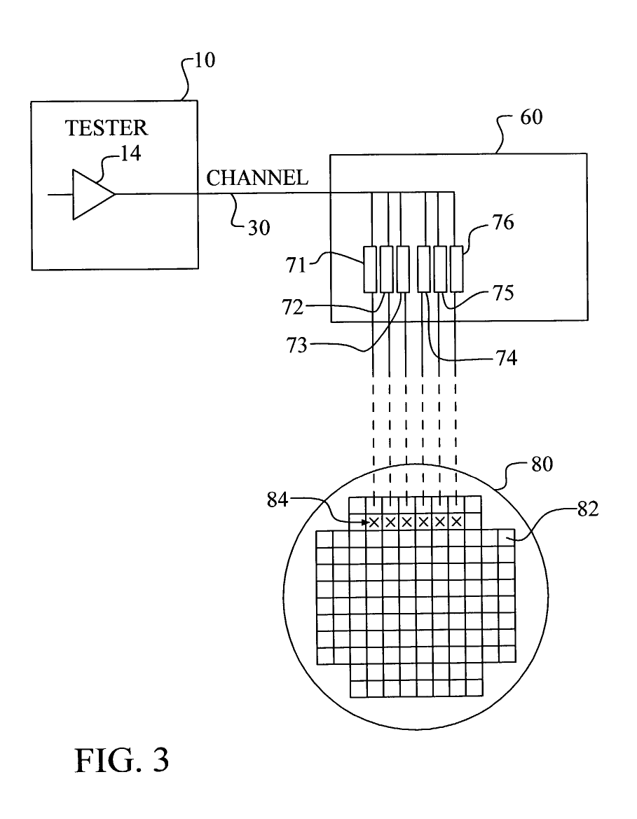

Referring now to FIG. 3, the preferred embodiment, tester apparatus is applied to testing multiple die on a semiconductor wafer. In this case, an integrated circuit wafer 80 comprises a plurality of circuit die 82. Each die 82 comprises a common circuit that requires functional testing. A probe card 60 is used to electrically couple the tester 10 to a DUT die test group 84. In this schematic, the probe card 60 is capable of connecting to a group of six die 84 on the wafer 80. To keep the schematic simple, only a single channel CHANNEL 30 of the tester is shown connected to the probe card. In reality, a large number of input and output channels would be connected from the tester 10 to the probe card 60. The probe card 60 preferably can be indexed across the wafer 80 to sequentially test every die 82 on the wafer 80.

As an important feature, auto-reset fuses 71-76 are included on the probe card 60. The auto-reset fuses 71-76 are in the current path between the tester output CHANNEL 30 and each die in the DUT group 84. Alternatively, the auto-reset fuses could be included on a performance card or on a test head structure. Other arrangements could be used while keeping within the scope of the invention.

The present invention can be applied to any tester output-DUT input combination to provide shorting isolation. Alternatively, the DUT input could be a bi-directional pin that is capable of both input and output operation. In this case, the auto-reset fuse facilitates testing the input performance of the bi-directional pin.

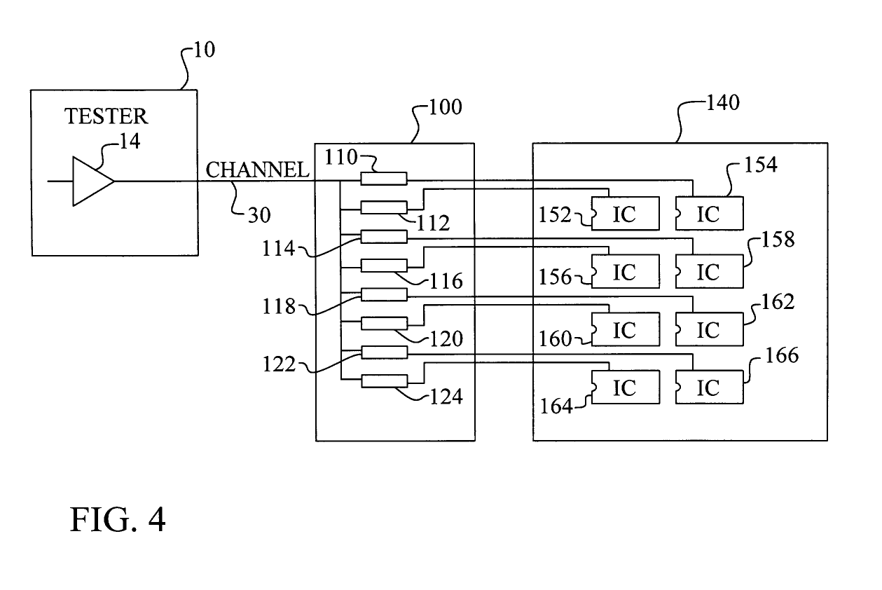

Referring now to FIG. 4, the preferred embodiment tester apparatus is applied to testing multiple, packaged integrated circuit devices. In this case, the DUT group comprises a group of packaged devices 152 through 166. The packaged devices are loaded onto a board 140 that may comprise, for example, an array of sockets for coupling the tester 10 signals to the DUT signals. A plurality of auto-reset fuses 110 through 124 is placed in the path between the tester output channel CHANNEL 30 and the plurality of DUT input signals. The auto-reset fuses 110 through 124 may be placed, for example, on a load board 100, a performance board, or on the packaged device socket board. Other arrangements could be used while keeping within the scope of the invention.

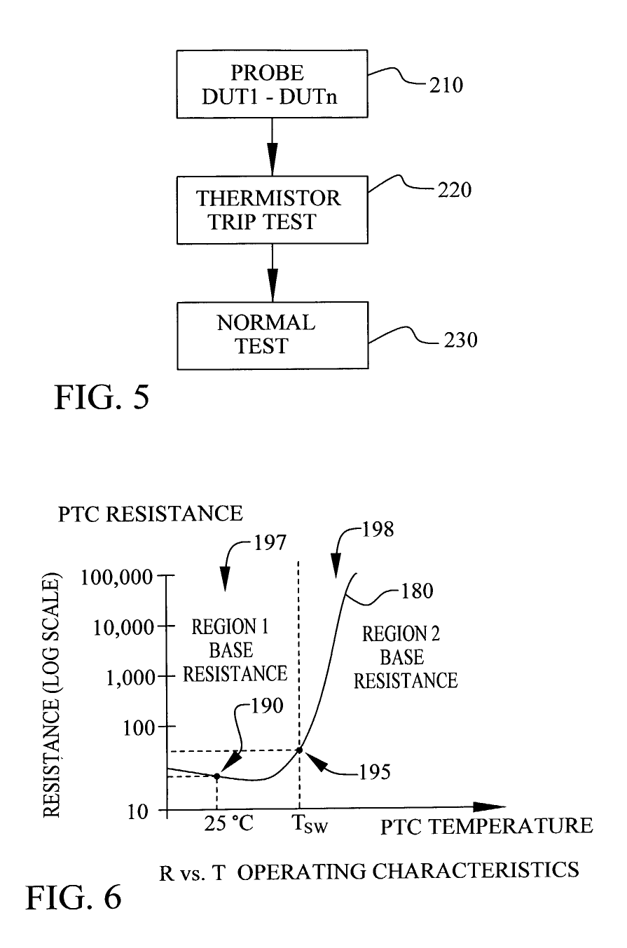

Referring now to FIG. 5, the preferred embodiment, simultaneous test method of the present invention is shown. The preferred embodiment test method comprises, first, probing a plurality of circuit devices DUT1 through DUTn in step 210. This probing may comprise, for example, probing a group of die on a wafer or loading a group of packaged parts on to a socket board. Each DUT has at least one input signal. A tester output signal is coupled to the input signals of the plurality of circuit devices DUT1-DUTn through a plurality of auto-reset fuses as discussed above. The auto-reset fuses automatically switch from low impedance during low current to high impedance during high current. The auto-reset fuses automatically switch from high impedance to low impedance after a waiting time.

The plurality of circuit devices is next tested by forcing a voltage on the tester output in step 220. This test is called a thermistor trip test. The thermistor trip test 220 is preferably performed prior to the normal, functional test in step 230. Any shorted input signals will be isolated during the trip test 220 by tripping the auto-reset fuses. By performing the thermistor trip test 220 first, the normal test 230 will see no interference from shorted input pins. Therefore, good circuits will not be scrapped. Note that the normal test 230 is run immediately after the trip test 220 so that any thermistor that has tripped to REGION 2 operation will remain in REGION 2 during the normal test duration. After the completion of the normal test 230, the sequence is repeated. The time necessary for probing the next group of DUT1-DUTn is sufficient to allow any tripped thermistor to cool down to REGION 2 operation.

During the trip test 220, the tester preferably drives the output, at different times in the test sequence, to either or to both the DUT high supply and the DUT ground reference. This will effectively detect if a DUT input pin is shorted to the high supply or to the ground reference.

The advantages of the present invention may now be summarized. An effective apparatus for simultaneously testing a plurality of circuit devices is achieved. The apparatus for simultaneously testing devices prevents a short on any of the multiple devices under test from interfering with testing of the other devices. The shorting isolation uses an auto-reset fuse between the shared, tester output channel and the multiple device inputs. The auto-reset fuse does not require a control signal. The auto-reset fuse is tripped under high current and is reset to the non-tripped state by a short wait time. Finally, a method of simultaneous testing a plurality of circuit devices is achieved. The method automatically isolates shorted devices from other devices without reducing device yield.

As shown in the preferred embodiments, the novel apparatus and method provide an effective alternative to the prior art.

While the invention has been particularly shown and described with reference to the preferred embodiments thereof, it will be understood by those skilled in the art that various changes in form and details may be made without departing from the spirit and scope of the invention.

What is claimed is:

1. An apparatus for simultaneously testing a plurality of circuit devices, said apparatus comprising:
a tester having at least one output signal;
a plurality of circuit devices each having at least one input signal; and
a plurality of auto-reset fuses wherein each said auto-reset fuse is coupled between said tester output signal and one of said input signals of said plurality of circuit devices, wherein said auto-reset fuses automatically switch from low impedance during low current to high impedance during high current, and wherein said auto-reset fuses automatically switch from high impedance to low impedance after a waiting time.

2. The apparatus according to claim 1 wherein said circuit devices comprise die on a semiconductor wafer.

3. The apparatus according to claim 1 wherein said circuit devices comprise packaged integrated circuit devices.

4. The apparatus according to claim 1 wherein said auto-reset fuses comprise positive temperature coefficient thermistors.

5. The apparatus according to claim 1 wherein said auto-reset fuses are placed on a probe card.

6. The apparatus according to claim 1 wherein said input signals of said circuit devices comprise bi-directional pins.

7. The apparatus according to claim 1 wherein said tester is capable of forcing a voltage on said tester output signal to test for a shorted condition.

8. An apparatus for simultaneously testing a plurality of circuit devices, said apparatus comprising:
a tester having at least one output signal;
a plurality of circuit devices each having at least one input signal; and
a plurality of auto-reset fuses wherein each said auto-reset fuse is coupled between said tester output signal and one of said input signals of said plurality of circuit devices, wherein said auto-reset fuses automatically switch from low impedance during low current to high impedance during high current, wherein said auto-reset fuses automatically switch from high impedance to low impedance after a waiting time, and wherein said auto-reset fuses comprise positive temperature coefficient thermistors.

9. The apparatus according to claim 8 wherein said circuit devices comprise die on a semiconductor wafer.

10. The apparatus according to claim 8 wherein said circuit devices comprise packaged integrated circuit devices.

11. The apparatus according to claim 8 wherein said auto-reset fuses are placed on a probe card.

12. The apparatus according to claim 8 wherein said input signals of said circuit devices comprise bi-directional pins.

13. The apparatus according to claim 8 wherein said tester is capable of forcing a voltage on said tester output signal to test for a shorted condition.

14. A method for simultaneously testing a plurality of circuit devices, said method comprising:
providing a plurality of circuit devices each having at least one input signal;
coupling a tester output signal to said input signals of said plurality of circuit devices through a plurality of auto-reset fuses wherein said auto-reset fuses automatically switch from low impedance during low current to high impedance during high current, and wherein said auto-reset fuses automatically switch from high impedance to low impedance after a waiting time; and
testing said plurality of circuit devices by forcing a voltage on said tester output wherein any shorted said input signals will be isolated by said auto-reset fuses.

15. The method according to claim 14 wherein said circuit devices comprise die on a semiconductor wafer.

16. The method according to claim 14 wherein said circuit devices comprise packaged integrated circuit devices.

17. The method according to claim 14 wherein said auto-reset fuses comprise positive temperature coefficient thermistors.

18. The method according to claim 14 wherein said auto-reset fuses are placed on a probe card.

19. The method according to claim 14 wherein said input signals of said circuit devices comprise bi-directional pins.

20. The method according to claim 14 wherein said voltage comprises one of the group consisting of: the supply voltage for said circuit devices and the ground reference voltage of said circuit devices.
